(19) United States
(12) Patent Application Publication
(10) Pub. No.: US 2014/0144477 A1
(43) Pub. Date: May 29, 2014

(54) THERMOELECTRIC NANOCRYSTAL COATED GLASS FIBER SENSORS

(71) Applicants: Yue Wu, West Lafayette, IN (US); Scott Finefrock, West Lafayette, IN (US)

(72) Inventors: Yue Wu, West Lafayette, IN (US); Scott Finefrock, West Lafayette, IN (US)

(73) Assignee: PURDUE RESEARCH FOUNDATION, West Lafayette, IN (US)

(21) Appl. No.: 14/167,111

(22) Filed: Jan. 29, 2014

Related U.S. Application Data
(63) Continuation-in-part of application No. PCT/US2012/050485, filed on Aug. 11, 2012.
(60) Provisional application No. 61/758,251, filed on Jan. 29, 2013.
(60) Provisional application No. 61/522,680, filed on Aug. 11, 2011.

(51) Int. Cl. H01L 35/16

(52) U.S. Cl. CPC H01L 35/16
USPC 136/201; 136/236.1; 136/238; 136/239; 136/241

(57) ABSTRACT

This disclosure examines using lead telluride nanocrystals as well as other materials suitable for thermoelectric conversion, particularly materials with high Figure of Merit values, as coatings on flexible substrates. This disclosure also examines using flexible substrates with lead telluride nanocrystal coatings as sensors.

### CROSS REFERENCE TO RELATED APPLICATION

This application claims the benefit of priority to U.S. Provisional Patent Application Ser. No. 61/758,251, filed Jan. 29, 2013, and as a continuation-in-part to International Patent Application No. PCT/US2012/050485, filed Aug. 11, 2012, the International Patent Application claiming priority to U.S. Provisional Application No. 61/522,680, filed Aug. 11, 2011, the disclosures of which are hereby expressly incorporated by reference.

### GOVERNMENT RIGHTS

This invention was made with government support under FA9550-12-1-0061 awarded by United States Air Force Office of Scientific Research (USAF/AFOSR). The government has certain rights in the invention.

### FIELD OF THE INVENTION

This disclosure generally relates to material suitable for thermoelectric conversion and particularly to materials with high Figure of Merit. This disclosure also generally relates to using flexible substrates with lead telluride nanocrystal coatings as sensors.

### BACKGROUND OF THE INVENTION

During the last hundreds of years, fossil fuels (including coal, petroleum, and natural gas) have been used as a main source of energy. Examples of energy conversion include operating power plants which may burn coal to produce electricity, operating internal combustion engines which burn petroleum to produce motion, lighting lamps which may burn natural gas to give off light, etc. Production of thermal energy is a byproduct of each of these forms of energy conversion, and in almost every energy converting activity. Currently, most of the produced thermal energy is lost. It would be beneficial to reclaim a portion of the thermal energy and convert it to a useful form of energy.

Thermoelectric (TE) devices provide one way to convert thermal energy into electrical energy. A thermoelectric device positioned between a hot reservoir and a cold reservoir can convert the thermal difference between these reservoirs into an electrical voltage. Referring to FIG. 5, a schematic of an application of prior art use of thermoelectric material is depicted.

The mechanism by which thermal energy is converted to electrical voltage is commonly measured by the Seebeck effect. The Seebeck effect can be explained as follows. A thermal gradient, ΔT=T_{H}−T_{C} (see FIG. 4), can generate a voltage ΔV. The relationship between the thermal gradient ant the voltage is known as the Seebeck effect. The generated voltage is governed by Formula 1:

$$S = \frac{Δ V}{Δ T}$$

where S is Seebeck coefficient,

ΔV is the magnitude of the generated voltage; and

ΔT is the thermal gradient.

In application, the higher the Seebeck coefficient the higher voltage ΔV generated for the same thermal gradient ΔT. Whether the Seebeck coefficient is a positive or negative number depends on whether electrical charge carriers are holes or electrons.

The Figure of Merit is one way to measure the efficiency of the thermoelectric material and structure. The Figure of Merit is may be denoted as ZT and may be expressed as Formula 2:

$$Z T = \frac{{S}^{2} σ}{κ} T$$

where S is the Seebeck coefficient,

σ is the electrical conductivity,

κ is thermal conductivity, and

T is the temperature.

As apparent from Formula 2, to achieve a high figure of merit, the thermoelectric material requires a low thermal conductivity and a high electrical conductivity. Low thermal conductivity slows heat transfer from the hot body to the cold body. The high electrical conductivity lowers electrical losses due to electrical resistance. For bulk materials, an increase in S usually results in a decrease in a. A decrease in the electrical conductivity leads to a decrease in the thermal conductivity as indicated by the Wiedemann-Franz law. Application of the Wiedemann-Franz law produces a barrier for the practical applications of thermoelectric (TE) materials.

Great efforts have been made to incorporate nanostructure materials into thermoelectric applications because of potential enhancement to Figure of Merit (ZT) due to quantum confinement. When the dimensions of material are reduced to nanometer scale, quantum confinement is introduced, altering the electronic structure. In quantum confinement, the number of available energy states is reduced causing a larger occupancy of the remaining states and a greater difference in energy between states. Sharp peaks in the electronic density of states may cause high power factor and thus an increased Figure of Merit (ZT). Reduced dimensions of material can also increase phonon scattering by introduction of interfaces and surfaces, which can reduce thermal conductivity, resulting in improvement of ZT.

Different materials have been investigated to improve the Figure of Merit. Bismuth telluride (Bi₂Te₃), and lead telluride (PbTe) are examples of thermoelectric materials being investigated. Lead (II) telluride (also known as the naturally occurring mineral altaite) has attracted much interest due to its excellent thermoelectric properties including a low level of thermal conductivity. However, many potential applications of thermoelectric materials have not been realized because most of the materials are rigid and cannot be made into desirable shapes.

Therefore, it is desirable to find a straightforward and scalable way to make flexible thermoelectric materials with very low thermal conductivity and high Figure of Merit (ZT) values that can be easily made into different shapes to make efficient flexible, wearable or even portable thermoelectric devices for purposes of energy conversion.

### SUMMARY OF THE INVENTION

The present disclosure includes a thermoelectric structure, comprising, a flexible substrate, and an electrically conducting coating on the flexible substrate. In some embodiments, the electrically conducting coating is a layer of nanocrystals coated over the flexible substrate.

The present disclosure also includes a method of coating lead telluride nanocrystals on a flexible substrate, the method comprising the steps of synthesizing lead telluride nanocrystals in solution, comprising the steps of, degassing and drying a first solution of lead oxide, oleic acid and 1-octodecene at 140° C. for at least approximately one hour under vacuum, contacting the first solution with a second solution of tri-n-octylphosphine and tellurium, wherein the second solution is prepared in a glovebox, quenching the reaction by immersing the mixture in a water bath, and contacting the reaction mixture with hexane; coating lead telluride nanocrystals on a flexible substrate, comprising the steps of, contacting flexible substrate to lead telluride nanocrystals, drying nanocrystal coated flexible substrate, contacting nanocrystal coated flexible substrate with hydrazine aqueous solution, contacting nanocrystal coated flexible substrate with acetonitrile; and repeating each coating step until nanocrystals form a uniform film on nanocrystal coated flexible substrate, and annealing nanocrystal coated flexible substrate to form a uniform layer of nanocrystal on flexible substrate.

It will be appreciated that the various apparatus and methods described in this summary section, as well as elsewhere in this application, can be expressed as a large number of different combinations and subcombinations. All such useful, novel, and inventive combinations and subcombinations are contemplated herein, it being recognized that the explicit expression of each of these combinations is unnecessary.

### BRIEF DESCRIPTION OF THE DRAWINGS

Some of the figures shown herein may include dimensions. Further, some of the figures shown herein may have been created from scaled drawings or from photographs that are scalable. It is understood that such dimensions, or the relative scaling within a figure, are by way of example, and not to be construed as limiting.

FIG. 1a is a schematic depicting a coating procedure of bare glass fibers and lead telluride (PbTe) coated glass fibers.

FIG. 1aa depicts an image of bare glass fibers.

FIG. 1ab depicts an image of lead telluride (PbTe) coated glass fibers.

FIG. 1b depicts a scanning electron microscopy image of PbTe nanocrystals coated glass fibers. The insert in FIG. 1b depicts a scanning electron microscopy image of the PbTe nanocrystals coated glass fibers at further magnification.

FIG. 1c depicts a transmission electron microscopy image of PbTe nanocrystals after annealing.

FIG. 2a depicts X-Ray Diffraction (XRD) patterns of PbTe nanocrystals for 1) before annealing, and 2) after annealing.

FIG. 2b depicts transmission electron microscopy images of PbTe nanocrystals with an average diameter of about 13±1 nm. The insert in FIG. 2b is a graph depicting particle size distribution.

FIG. 2c depicts high-resolution transmission electron microscopy images of a PbTe nanocrystal.

FIG. 3a depicts a graph of electrical conductivity for PbTe nanocrystals on a flexible substrate according to an embodiment of the present disclosure. The graph illustrates electrical conductivity measured in siemens per meter, vs. temperature, measured in Kelvin (K).

FIG. 3b depicts a graph of Seebeck coefficient for PbTe nanocrystals on a flexible substrate according to an embodiment of the present disclosure. The graph illustrates Seebeck coefficient measured in microvolts per K, vs. temperature, measured in K.

FIG. 3c depicts a graph of power factor for PbTe nanocrystals on a flexible substrate according to an embodiment of the present disclosure. The graph illustrates power factor measured in miliwatts per meter per K squared, vs. temperature, measured in K.

FIG. 3d depicts a graph of thermal conductivity for PbTe nanocrystals on a flexible substrate according to an embodiment of the present disclosure. The graph illustrates thermal conductivity measured in watts per meter and K, vs. temperature, measured in K.

FIG. 3e depicts a graph of Figure of Merit (ZT) for PbTe nanocrystals on a flexible substrate according to an embodiment of the present disclosure. The graph illustrates Figure of Merit (ZT) vs. temperature, measured in K.

FIG. 3f depicts a histogram of highest ZT values obtained from different measurements.

FIG. 4a depicts a picture of a measurement device with bended fibers according to an embodiment of the present disclosure, showing flexibility of the fibers and the bending angle of 84.5°.

FIG. 4b is a graph depicting the electrical conductivity for PbTe nanocrystals coated on the bent fibers of FIG. 4a. The graph illustrates electrical conductivity measured in siemens per meter, vs. temperature, measured in K.

FIG. 4c is a graph depicting the Seebeck coefficient for PbTe nanocrystals coated on the bent fibers of FIG. 4a. The graph illustrates Seebeck coefficient measured in microvolts per K, vs. temperature, measured in K.

FIG. 4da is a graph depicting a comparison of ZT vs. temperature obtained from flat and bent PbTe nanocrystal coated glass fibers.

FIG. 4db is a graph depicting a comparison of power factor, measured in miliwatts per meter per K vs. temperature obtained from flat and bent PbTe nanocrystal coated glass fibers.

FIG. 5 is a schematic of an application of prior art use of thermoelectric material.

FIG. 6a is a schematic and a perspective view of an experimental apparatus for determining voltage across fibers due to nearby motion.

FIG. 7 includes multiple panels, beginning with Panel B. Panels B, D, and F are graphs depicting voltage across fibers in response to motion of a person walking/jogging in a straight line 0.43 m (˜20 s), 0.74 m (˜40 s), 1.04 m (˜60 s), 1.35 m (˜80 s), and 1.65 m (˜100 s) from the sensor at speeds of 0.95 m/s (Panel B), 1.43 m/s (Panel D), and 2.58 m/s (Panel F). Panels C, E, and G are graphs depicting standard deviations of five consecutive voltage points. Panel H is a graph depicting the standard voltage maxima as a result of motion at a given speed and distance from the sensor.

FIG. 8 is a graph depicting voltage vs. time for experiments in which a person lightly jogged past a suspended Au/Pd alloy coated fiber bundle at 20, 40, 60, 80, and 100 seconds.

FIG. 9 is a graph depicting the correlation between maximum voltage signal observed as a result of nearby jogging motion and sample resistance for Au/Pd coated glass fiber bundles.

FIG. 10 is a graph depicting voltage across a bundle of Au/Pd coated glass fibers over time during experiments with fruit flies.

FIG. 11 is a graph depicting voltage across a bundle of Au/Pd coated glass fibers immersed in salt water during experiments with underwater motion.

### DESCRIPTION OF THE PREFERRED EMBODIMENT

For the purposes of promoting an understanding of the principles of the invention, reference will now be made to the embodiments illustrated in the drawings and specific language will be used to describe the same. It will nevertheless be understood that no limitation of the scope of the invention is thereby intended, such alterations and further modifications in the illustrated device, and such further applications of the principles of the invention as illustrated therein being contemplated as would normally occur to one skilled in the art to which the invention relates. At least one embodiment of the present invention will be described and shown, and this application may show and/or describe other embodiments of the present invention. It is understood that any reference to “the invention” is a reference to an embodiment of a family of inventions, with no single embodiment including an apparatus, process, or composition that should be included in all embodiments, unless otherwise stated. Further, although there may be discussion with regards to “advantages” provided by some embodiments of the present invention, it is understood that yet other embodiments may not include those same advantages, or may include yet different advantages. Any advantages described herein are not to be construed as limiting to any of the claims. The usage of words indicating preference, such as “preferably,” refers to features and aspects that are present in at least one embodiment, but which are optional for some embodiments.

Although various specific quantities (spatial dimensions, temperatures, pressures, times, force, resistance, current, voltage, concentrations, wavelengths, frequencies, heat transfer coefficients, dimensionless parameters, etc.) may be stated herein, such specific quantities are presented as examples only, and further, unless otherwise explicitly noted, are approximate values, and should be considered as if the word “about” prefaced each quantity. Further, with discussion pertaining to a specific composition of matter, that description is by example only, and does not limit the applicability of other species of that composition, nor does it limit the applicability of other compositions unrelated to the cited composition.

What will be shown and described herein, along with various embodiments of the present invention, is discussion of one or more tests that were performed. It is understood that such examples are by way of example only, and are not to be construed as being limitations on any embodiment of the present invention. Further, it is understood that embodiments of the present invention are not necessarily limited to or described by the mathematical analysis presented herein.

Various references may be made to one or more processes, algorithms, operational methods, or logic, accompanied by a diagram showing such organized in a particular sequence. It is understood that the order of such a sequence is by example only, and is not intended to be limiting on any embodiment of the invention.

This document may use different words to describe the same element number, or to refer to an element number in a specific family of features (NXX.XX). It is understood that such multiple usage is not intended to provide a redefinition of any language herein. It is understood that such words demonstrate that the particular feature can be considered in various linguistical ways, such ways not necessarily being additive or exclusive.

What will be shown and described herein are one or more functional relationships among variables. Specific nomenclature for the variables may be provided, although some relationships may include variables that will be recognized by persons of ordinary skill in the art for their meaning. For example, “t” could be representative of temperature or time, as would be readily apparent by their usage. However, it is further recognized that such functional relationships can be expressed in a variety of equivalents using standard techniques of mathematical analysis (for instance, the relationship F=ma is equivalent to the relationship F/a=m). Further, in those embodiments in which functional relationships are implemented in an algorithm or computer software, it is understood that an algorithm-implemented variable can correspond to a variable shown herein, with this correspondence including a scaling factor, control system gain, noise filter, or the like.

### EXPERIMENTAL

### Preparation of Lead (II) Tellurium Nanocrystals

Tri-n-octylphosphine (TOP, 97%), 1-Octadecene (ODE, 90%), Oleic acid (OA, 90%), Lead (II) oxide (PbO, 99.9+%), Tellurium powder (99.8%), Hexane (98.5%), Acetone (99.5%), Hydrazine (98%) and Acetonitrile (99.8%) were used for synthesis of lead telluride (PbTe) nanocrystals under nitrogen (N2) using a Schlenk line.

PbTe nanocrystals were synthesized according to an exemplary process, as follows. 0.223 g PbO, 0.7 g OA and 5 g ODE are degassed and dried at 140° C. for at least 1 hour in a 50 mL round-bottom flask under vacuum. A TOP-Te solution is prepared in a glovebox with a concentration of approximately 0.75M and diluted to approximately 0.5M by ODE. 3 mL of 0.5M TOP-Te solution is then injected and reacted at 250° C. for 1 min. The reaction is then quenched by immersing the flask in a water bath. Once the temperature reached 70° C., 5 mL of hexane is injected and the flask is allowed to cool down to ambient temperature.

After cooling to room temperature, the reaction is then washed with a 1:1 volume ratio hexane/acetone pair for 3 times to remove any impurity.

Similar PbTe nanocrystal synthesis techniques have been reported several times previously. Others synthesize PbTe nanocrystals using similar procedures with slight adjustments. For example: i) squalane, diphenyl ether, or TOP can replace ODE as the reaction solvent, ii) lead acetate trihydrate can replace lead oxide, iii) ethanol can replace acetone as the precipitating agent during nanocrystal washing, iv) the reaction time and temperature can be varied significantly to achieve different nanocrystal sizes.

It is envisioned that several conditions can be modified within the scope of this present disclosure. For example, the concentration of washed PbTe nanocrystals dissolved in hexane or chloroform can be adjusted by simply adding acetone, centrifuging, pouring out the liquid supernatant, and adding a specific amount of solvent, such as chloroform or hexane. Therefore, if a large concentration is desired, washed nanocrystals could be dissolved in a very small amount of solvent.

### Example 1

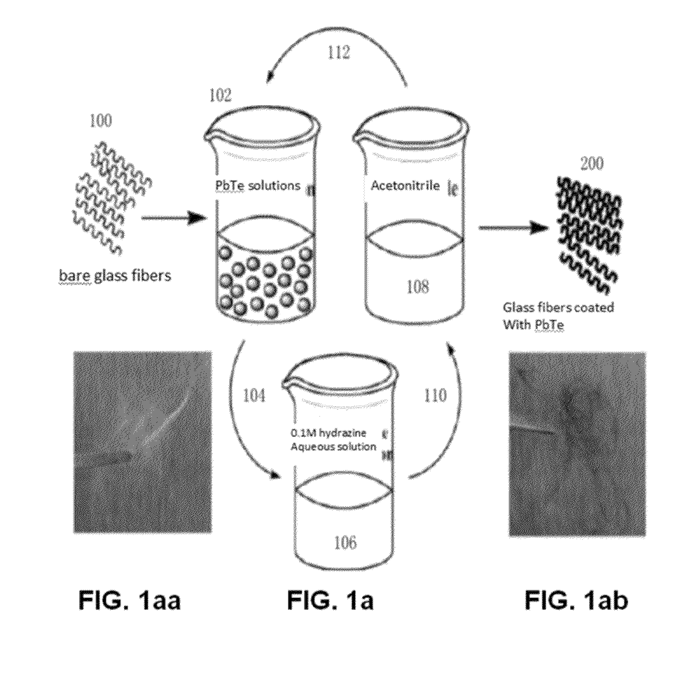

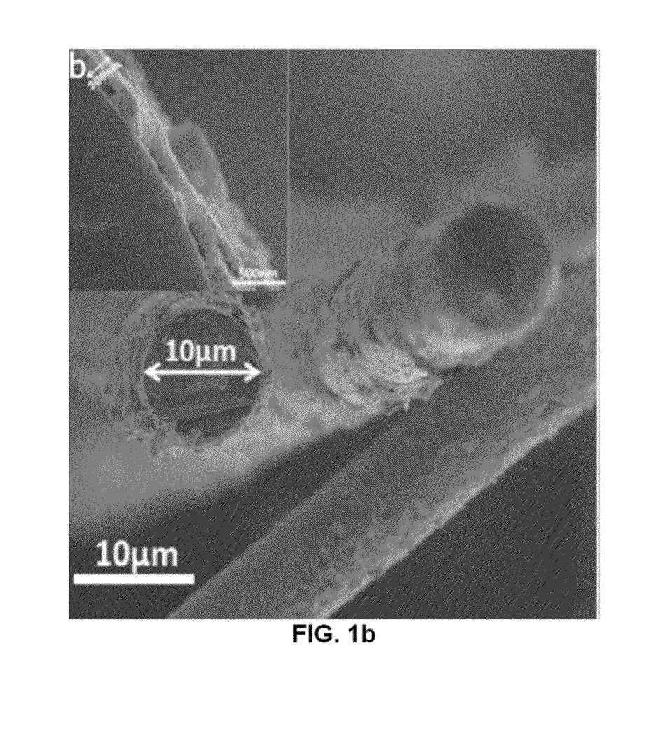

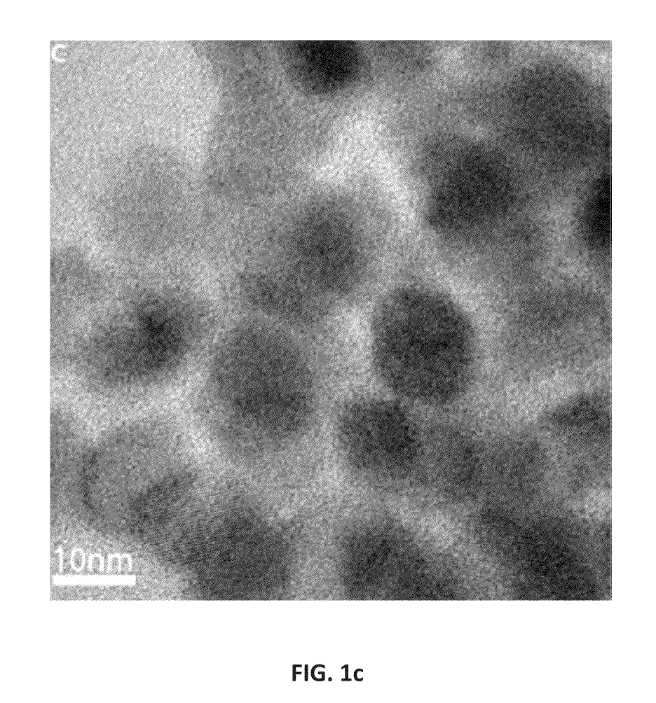

FIG. 1a depicts a schematic used for a coating procedure of flexible substrates 100, such as bare glass fibers 100, to create lead telluride (PbTe) coated glass fibers 200. As shown in FIG. 1a, procedure of coating 300 is as follows:

1) bare fluffy glass fibers 100 are dip-coated in PbTe nanocrystal solution 102,
a. coated glass fibers 100 are then taken out, as illustrated by arrow 104, and dried;

2) fibers 100 are dipped into 0.1M hydrazine aqueous solution 106 to get rid of excessive OA on the surface of fibers 100; and

3) 99.8% anhydrous acetonitrile 108 is used to wash and to remove hydrazine and dry in nitrogen flow.

After dipping flexible substrates 100 into PbTe nanocrystal solution 102, coated substrate 100 is dried for approximately 15 seconds to approximately 60 seconds. After dipping coated substrate 100 into hydrazine aqueous solution 106, substrate 100 is not formally dried. Rather coated substrate 100 is quickly transferred to the acetonitrile solution, as illustrated by arrow 110. After dipping coated substrate 100 in acetonitrile solution 108 coated substrate 100 is dried for approximately 2 minutes to approximately 3 minutes.

This procedure is repeated, as illustrated by arrow 112 until a uniform film of thermoelectric material is coating flexible substrate 100. Approximately twenty cycles of procedure 300 is typically enough to achieve a uniform film. Uniform means that the coating thickness is substantially the same everywhere. An objective measure of uniform is to measure and evaluate the thickness of the coating at several points on flexible substrate 100. It is envisioned that several conditions in procedure 300 could be modified which would require less than twenty cycles to produce the uniform film. It is envisioned that modification of these conditions is within the scope of this disclosure.

Two hours of approximately 300° C. annealing is used to remove organic ligands and form a uniform layer on glass fibers 100 to produce lead telluride (PbTe) coated glass fibers 200 for further measurements. FIG. 1c depicts transmission electron microscopy images of PbTe nanocrystals after annealing.

The flexible substrates, such as bare fluffy glass fibers, were estimated to be approximately 1-2 inches long. This length is difficult to estimate because the flexible substrate is handled in fiber bundles, not individual fibers.

Regarding the dip-coating procedure, it is envisioned that the hydrazine aqueous solution could be replaced with a hydrazine/acetonitrile solution to achieve the same results.

Spark plasma sintering is used to make PbTe nanocrystals coated glass fibers into pellets for thermal conductivity measurement.

Results

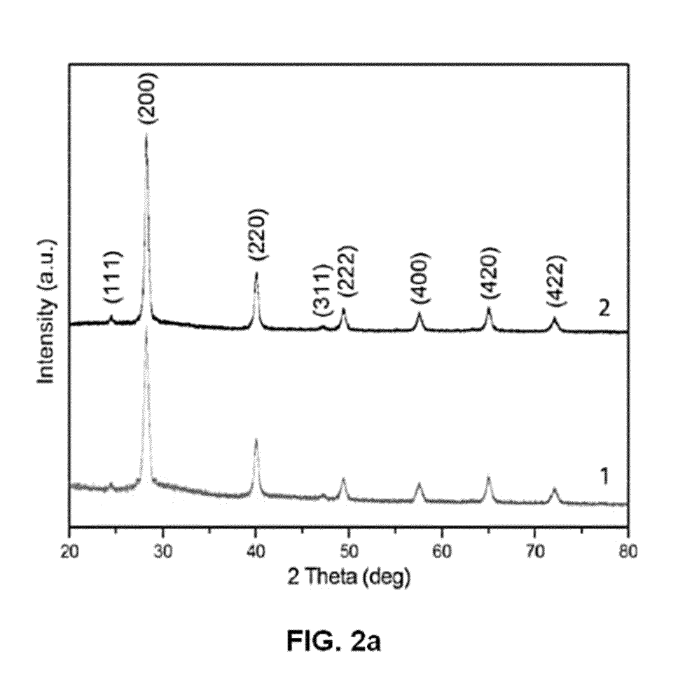

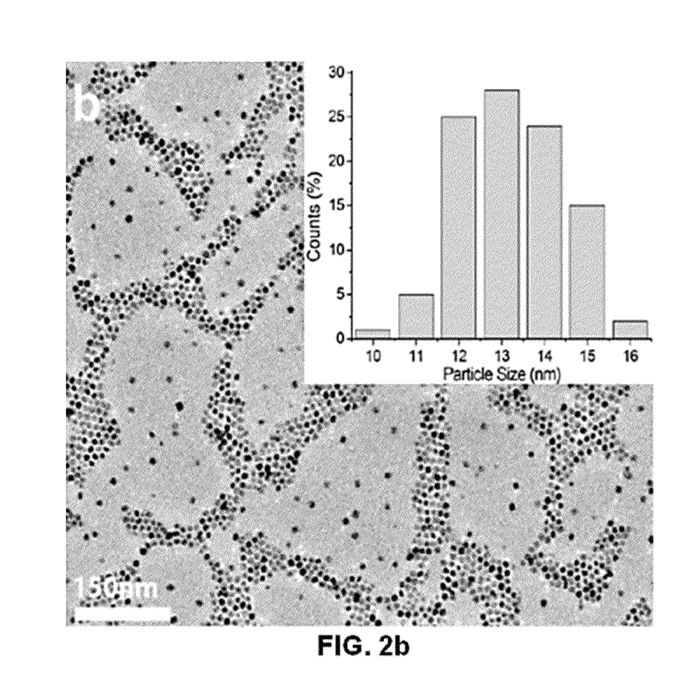

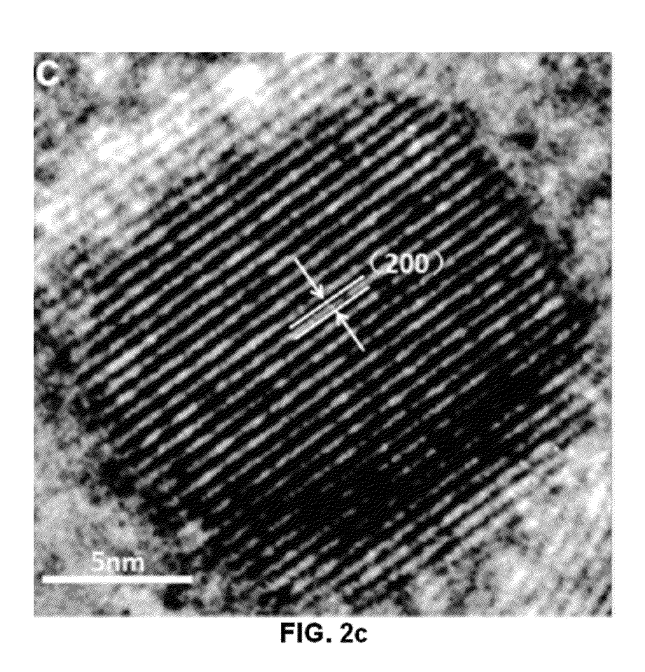

X-ray diffraction (XRD) studies (FIG. 2a) show the materials prepared according to the present disclosure are Altaite phase PbTe (JCPDS 38-1435), as correlated to a database maintained by the International Centre for Diffraction Data (ICDD) which was previously known as the Joint Committee on Powder Diffraction Standards (JCPDS). There is essentially no difference between the XRD patterns of samples before and after annealing, indicating that the PbTe nanocrystals remain the same as synthesized after the coating procedure. Low-resolution transmission electron microscopy (TEM) studies (FIG. 2b) show uniform nanocrystals with an average size (thickness) of about 13±1 nm (Inset, FIG. 2b). In high-resolution TEM image (FIG. 2c), it can clearly be seen that the distance between different crystal faces is 0.32 nm, indicating (200), which is the highest peak in XRD pattern for Altaite phase PbTe. At the same time, it shows that the PbTe nanocrystals are single-crystalline.

Scanning electron microscopy (SEM) studies (FIG. 1b) show the coated glass fibers have a uniform PbTe nanocrystal layer with a thickness of about 300 nm.

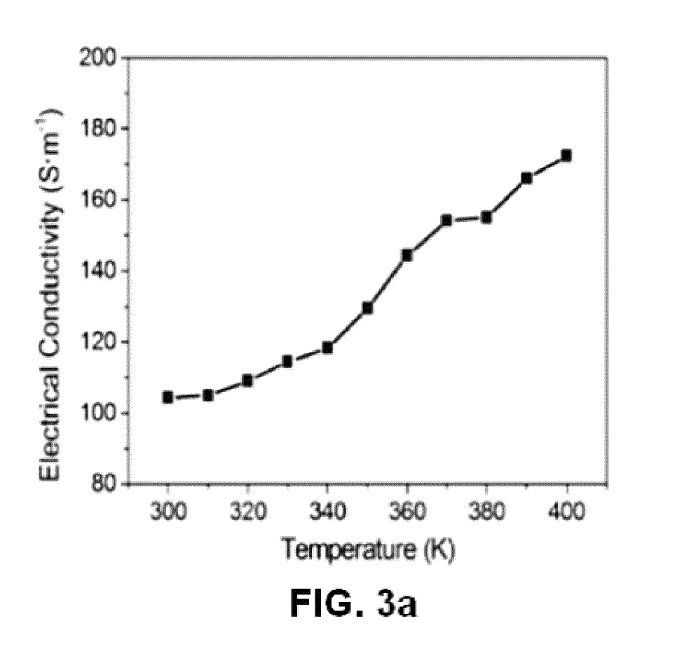

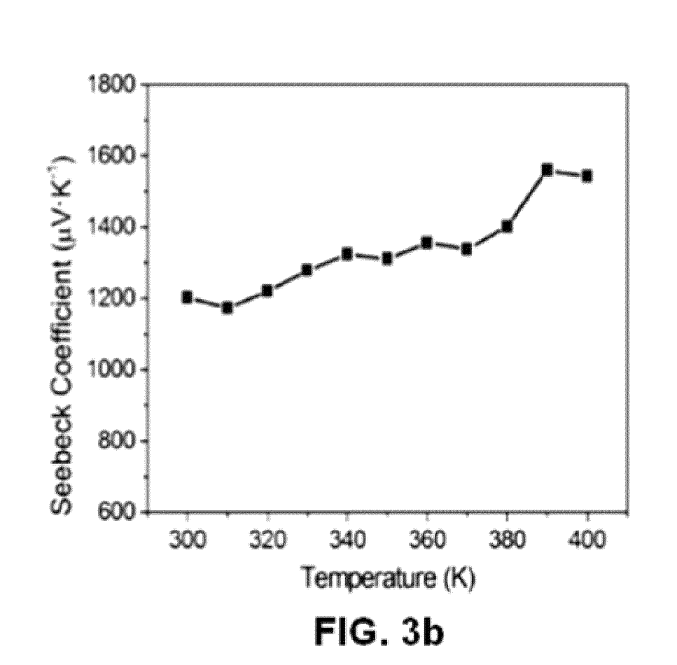

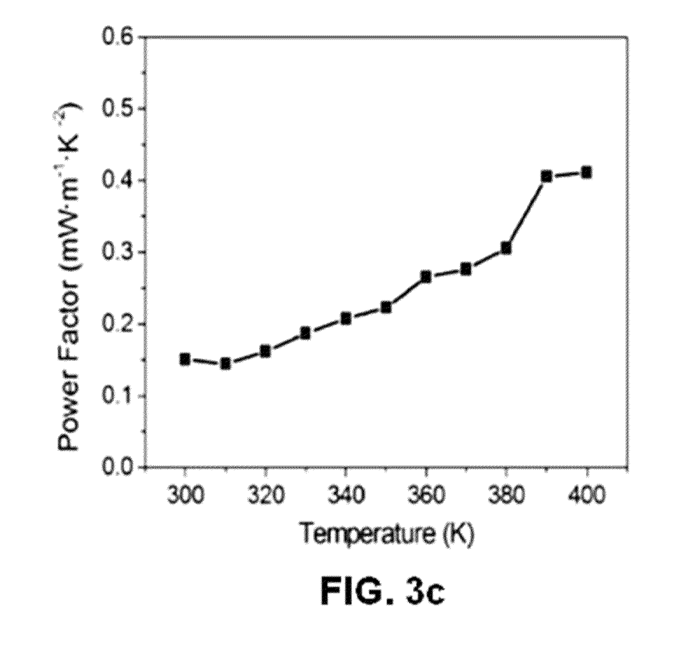

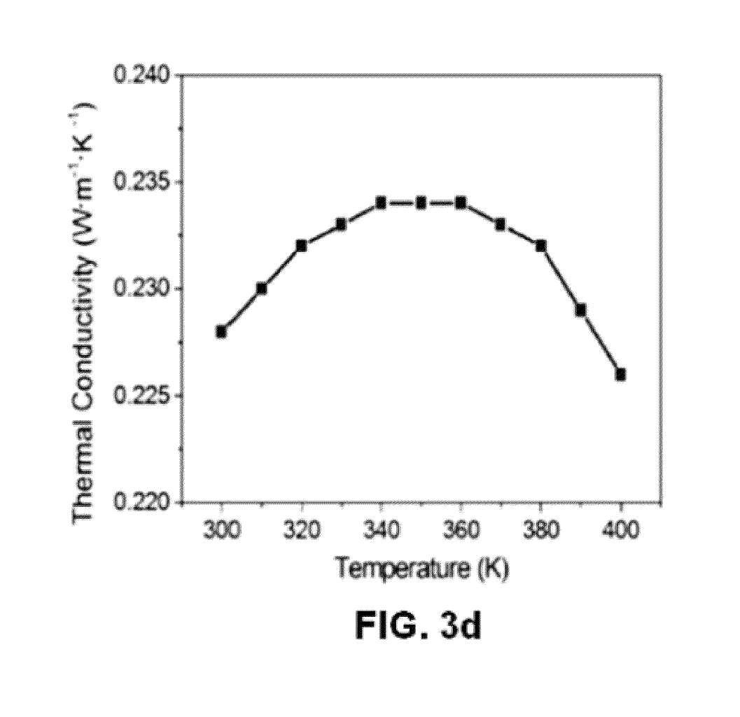

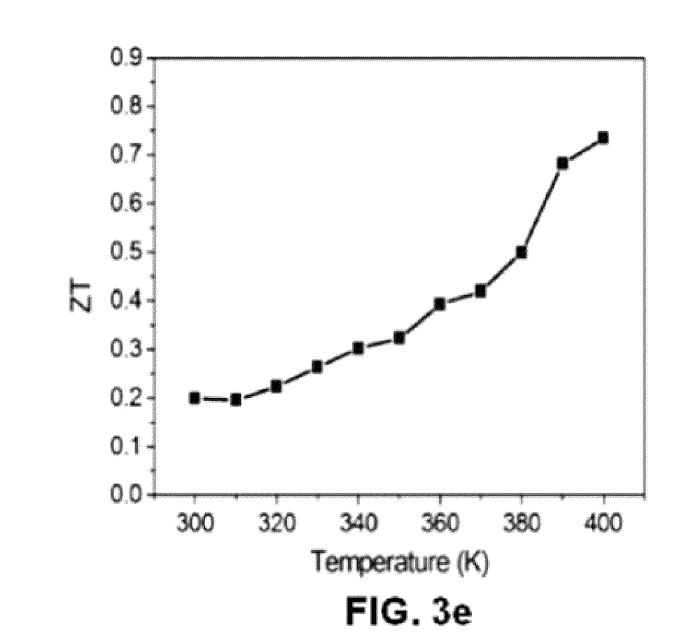

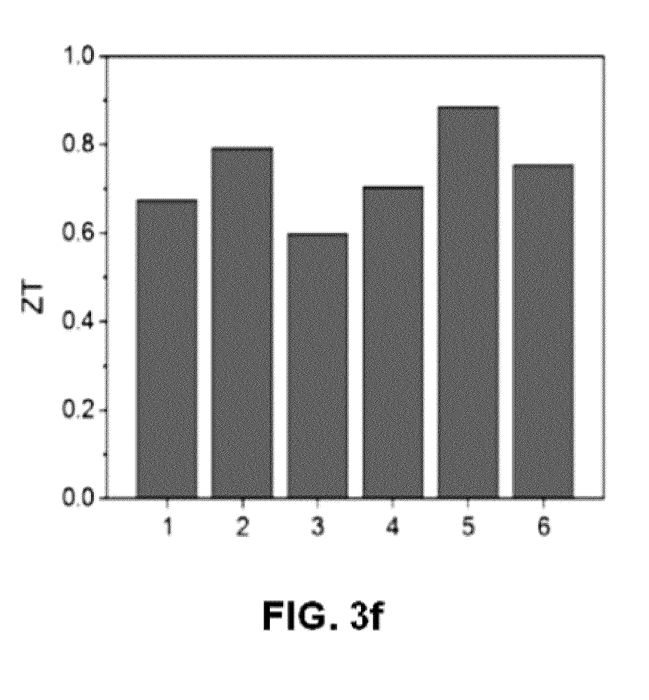

Electrical conductivity and the Seebeck coefficient of PbTe nanocrystals coated glass fibers have been investigated between 300 K and 400 K in the axial direction. The electrical conductivity (FIG. 3a) of the PbTe nanocrystals coated glass fibers increases from about 104.4 S·m⁻¹ at 300 K to about 172.4 S·m⁻¹ at 400 K. FIG. 3b depicts the temperature dependence of Seebeck coefficient of PbTe nanocrystals coated glass fibers. The positive Seebeck coefficient value indicates the p-type conduction. The Seebeck coefficient measurement shows an increasing trend from about 1201.71 μV·K⁻¹ at 300K to about 1542.4 μV·K⁻¹ at 400 K. Both electrical conductivity and Seebeck coefficient measurements for PbTe nanocrystals coated glass fibers give variable results depending on the sample tested. The results shown in FIG. 3a and FIG. 3b represent the highest values obtained for all samples tested. Furthermore, it should be noted that the Seebeck measurement system used to obtain the results in FIG. 3b was later found to yield values whose magnitudes are generally greater than values obtained from other instruments.

The thermal conductivity of PbTe nanocrystals coated glass fibers compressed by spark plasma sintering is measured through thermal diffusivity and specific heat and then calculated via the equation:

K=αpCₚ

wherein α is thermal diffusivity, p is the density, Cp is the specific heat.

The thermal conductivity (FIG. 3d) at 300 K is measured to be about 0.228 W·m⁻¹·K⁻¹ and goes up to about 0.234 W·m⁻¹·K⁻¹ around 350 K, and then down to about 0.226 W·m⁻¹·K. The calculated power factor for the spark plasma sintered PbTe nanocrystals coated glass fibers (FIG. 3c) increases from about 0.15 mW·m⁻¹·K⁻² to about 0.41 mW·m⁻¹·K⁻². The ZT for the PbTe nanocrystals coated glass fibers shown in FIG. 3e, calculated by using the data in FIGS. 3a, 3b, and 3d, increases from about 0.20 at 300K to about 0.73 at 400K. FIG. 3f depicts a histogram of highest ZT values obtained from different measurements.

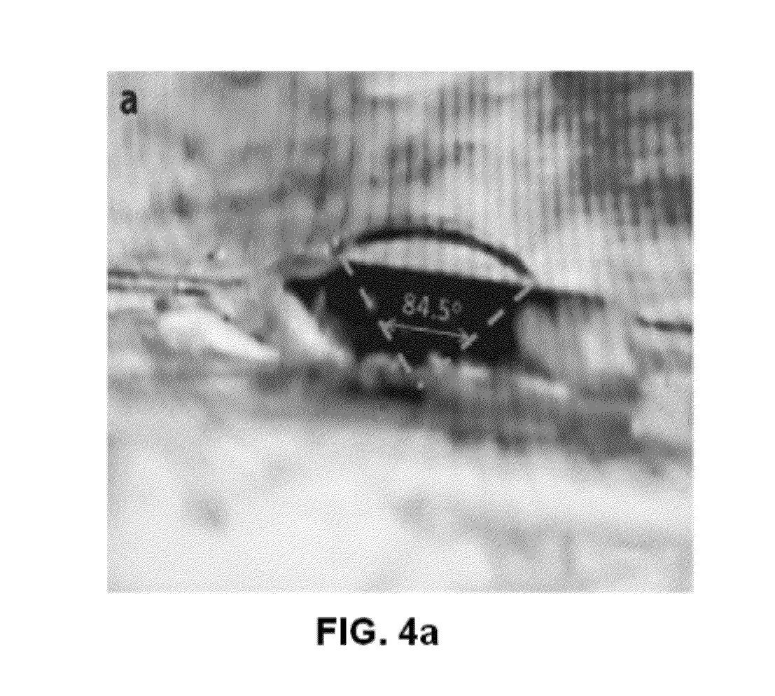

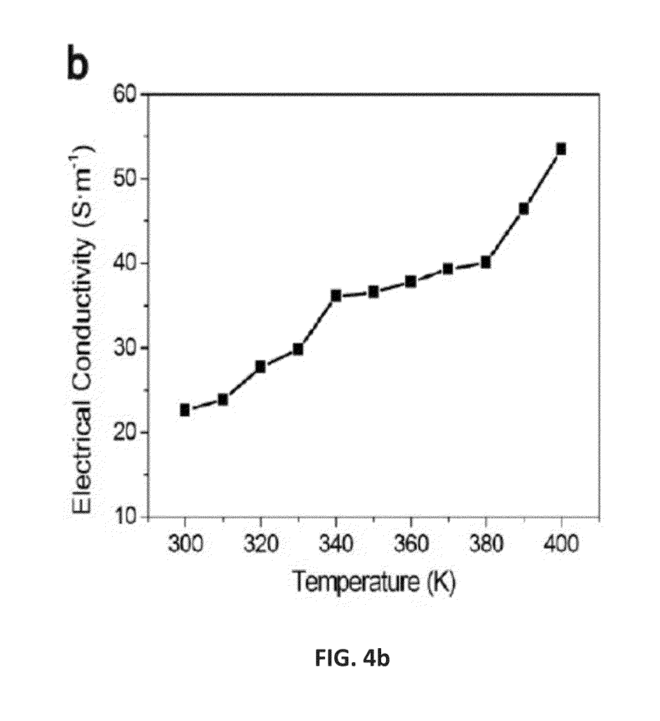

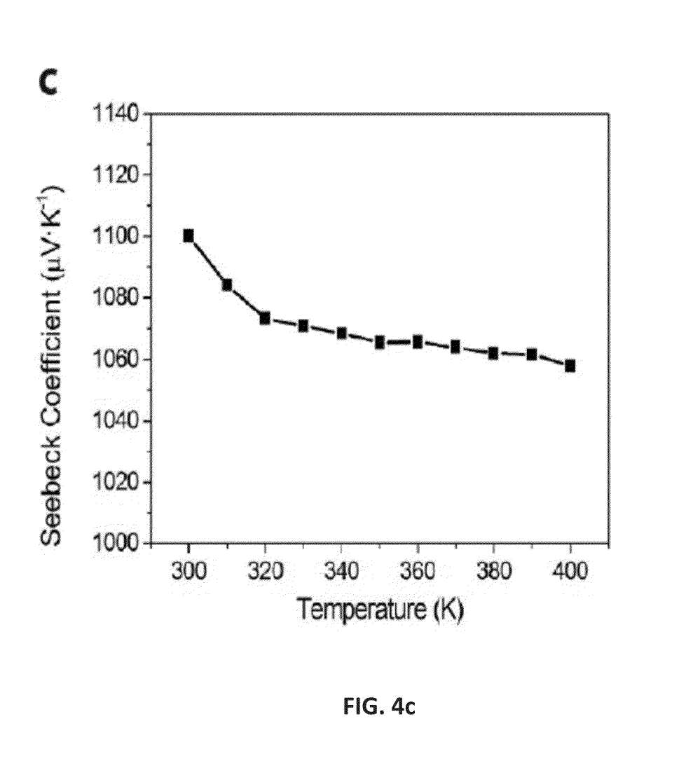

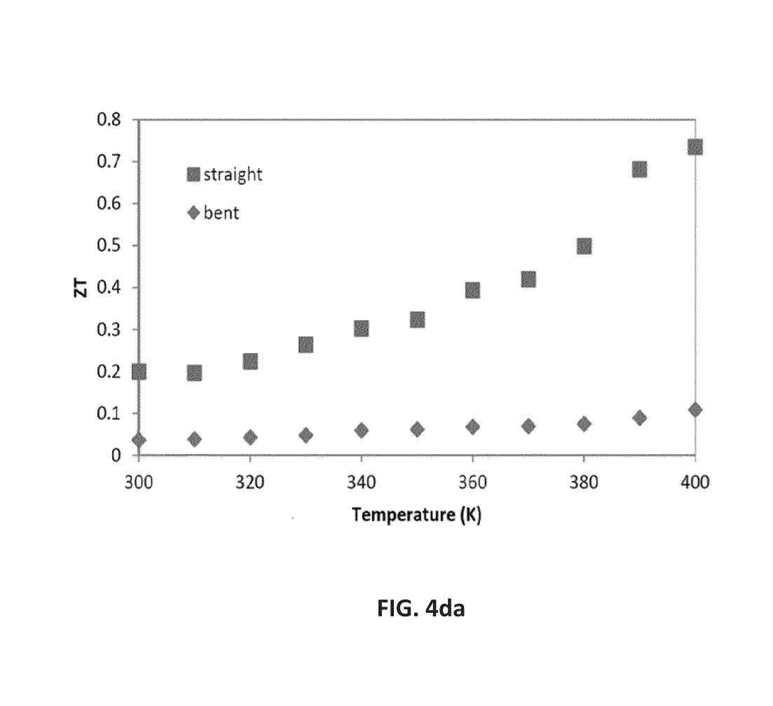

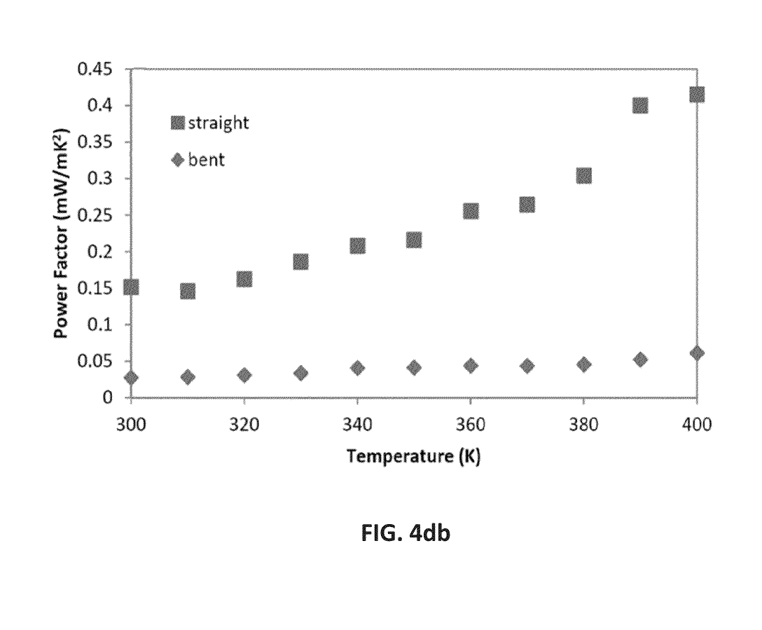

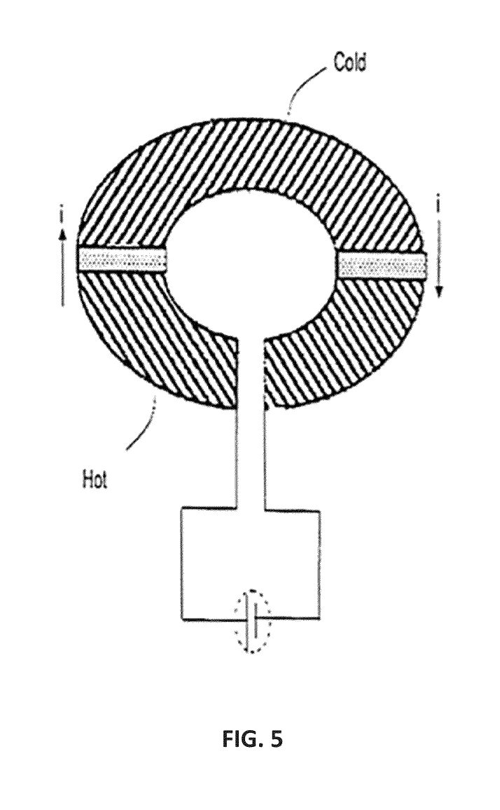

Additionally, thermoelectric properties of bended fibers were measured between 300K and 400K. The electrical conductivity (FIG. 4b) of bended fibers increases from about 22.7 S·m⁻¹ at 300 K to about 53.5 S·m⁻¹ at 400 K. FIG. 4c shows the temperature dependence of Seebeck coefficient of bended fibers. The positive Seebeck coefficient value indicates the p-type conduction. The Seebeck coefficient measurement shows a decreasing trend from 1100.2 μV·K⁻¹ at 300 K to 1058.0 μV·K⁻¹ at 400 K. The calculated power factor for bended fibers (FIG. 4da) increases from 0.027 mW·m⁻¹·K⁻² at 300 K to about 0.105 at 400 K. The ZT for bended fibers calculated using data from FIG. 4b, FIG. 4c, and FIG. 3d (FIG. 4db) increases from about 0.036 at 300 K to about 0.105 at 400 K. FIG. 4a depicts a curvature of about 84.5° during the electrical conductivity and Seebeck coefficient measurements.

Research in the field of perimeter intrusion detection systems (“PIDS”) is relatively slow moving, and new sensor technologies are not introduced often. Most PIDS research focuses on signal processing to improve the performance of available technology. Meanwhile this disclosure represents an entirely new sensor technology.

The coated fibers could be used as sensors, such as motion sensors. The coated fiber sensors have the advantages of being inexpensive, self-powered, and simple in design. In various embodiments, coated fiber sensors may be positioned on a surface, such as a floor or ground, underground or otherwise below a surface, immersed or submerged in a liquid, such as water, or suspended above a surface. By detecting changes in voltage or, put another way, the electrical field generated by the fiber, motion in the vicinity of the sensor may be detected.

Voltage develops in a scenario of human motion near bundles of glass fibers coated with a thin layer of an electrically conducting material. Initial experiments were performed using lead telluride nanocrystal coated glass fibers which were initially described in a Nano Letters publication, available at (http://pubs.acs.org/doi/abs/10.1021/nl300524j).

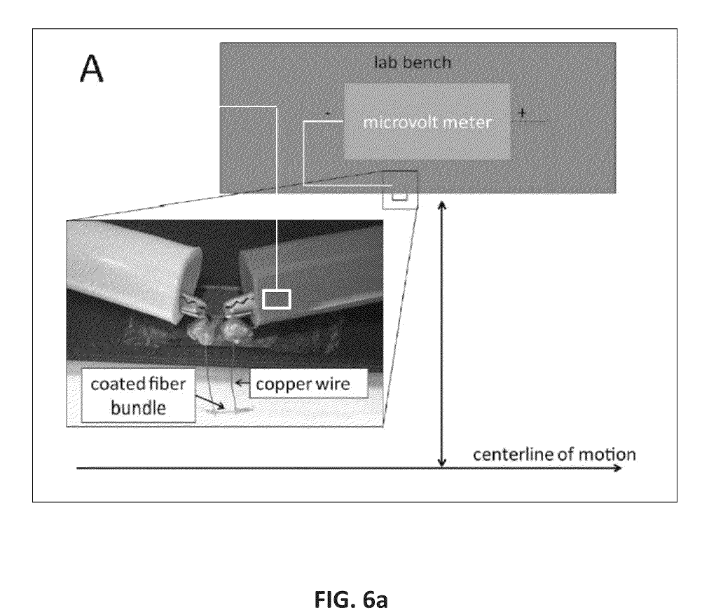

The experimental setup and sensor are shown in FIG. 6a. A bundle of lead telluride coated glass fibers is suspended across copper wires, making electrical connections using silver paint. One copper wire contacts the glass fibers at a first position and another copper wire contacts the glass fibers at a second position spaced apart from the first position. The copper wires are adhered to a glass support, which is mounted onto the edge of a lab bench. The voltage across the fibers is detected and measured by a device for detecting voltage, such as a voltmeter. In some embodiments, the device is a two terminal device, with one terminal connected to the first position by a first electrical lead and the other terminal connected to the second position by a second electrical lead.

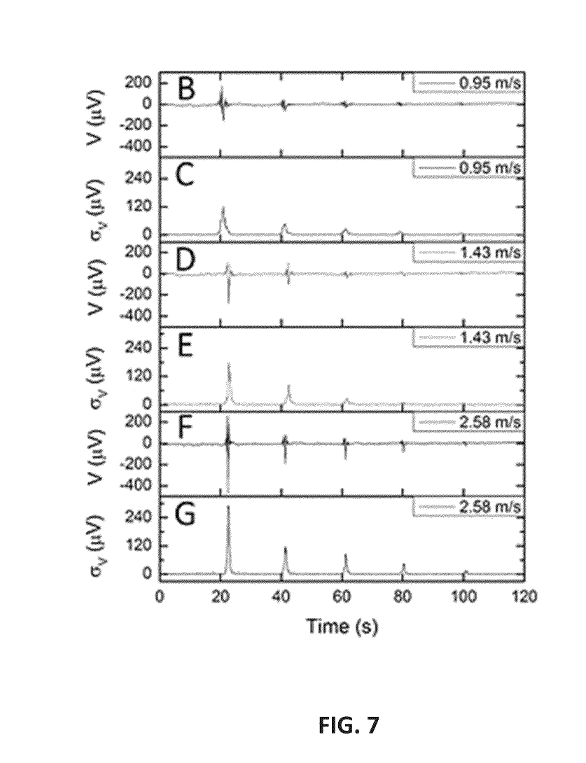

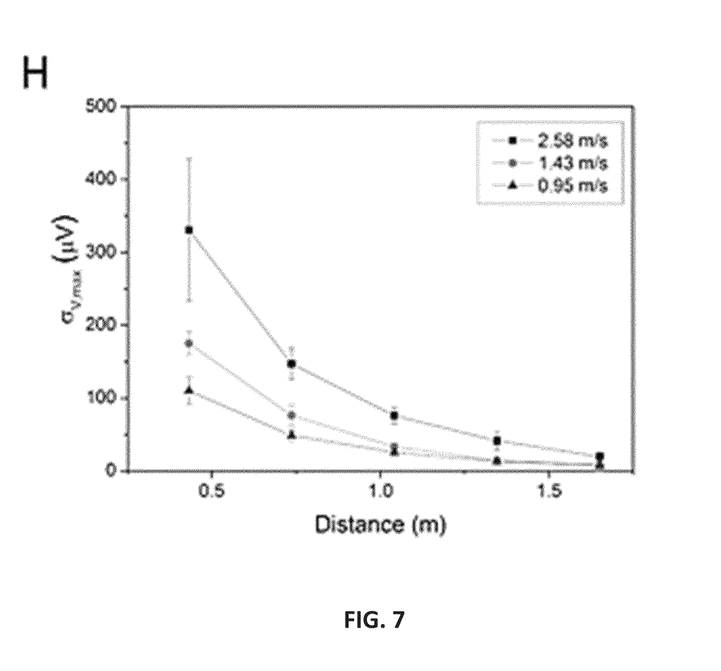

The voltage across the fiber bundle is measured and recorded while a person walks in straight line at a specified lateral distance from the fiber bundle. FIG. 7, panel B, shows the voltage across the fibers in response to a slow walking motion (0.95 m/s) at distances of 0.43 m, 0.74 m, 1.04 m, 1.35 m, and 1.65 m at times of 20 s, 40 s, 60 s, 80 s, and 100 s, respectively. The motion causes significant rapid changes in the fiber voltage, especially when the motion is in close proximity to the fibers. FIG. 7, panels D and F, show the results of similar experiments involving a moderate speed walking motion (1.43 m/s) and light jogging motion (2.58 m/s). In the case of the rapid motion, the voltage at 20 seconds decreases to even below −400 μV.

Signal patterns associated with alarm situations should be distinguishable from signal patterns associated with normal situations. Based on the data in FIG. 7, panel B, the slow motion far from the sensor is difficult to distinguish from background noise. A large signal to noise ratio is desirable for intruder detection devices to achieve a high probability of detection and a low false alarm rate. Simple data processing methods can be used to help distinguish voltage patterns associated with alarm and normal situations. Human motion induces rapid changes in the voltage, while background noise sources induce gradual changes in the voltage. Therefore the standard deviation of five consecutive voltage measurements (σᵥ) provides a processed voltage signal to clearly distinguish times of motion and no motion. FIG. 7, panels C, E, and G, show how σᵥ exhibits significant increases during nearby motion, yet is close to 0 μV during times without nearby motion.

Ten experiments were performed at each of three walking speeds and at each of five distances from the fibers for a total of 150 experiments. FIG. 7, panel H, shows a summary of the maximum value of σᵥ for each motion speed and distance from the sensor. The maximum value of σᵥ increases monotonically with motion speed and decreases monotonically with distance. If the sensor is used for intruder detection, quickly moving intruders can be easily by sensed at distances of at least 1.5 m. Slowly moving intruders can still be detected at distances of 1.5 m, although the signal is much higher at distances of 1.0 m or less.

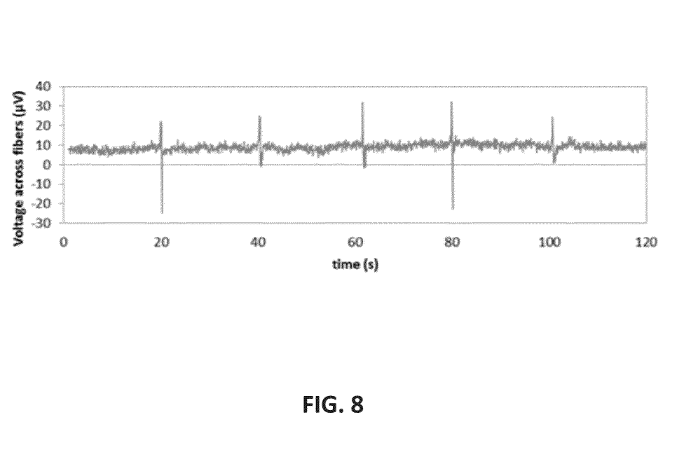

Similar experiments performed on glass fibers coated with thin layers of Au/Pd alloy or platinum produced similar results. For example, FIG. 8 shows data for voltage vs. time for experiments in which a person lightly jogged past a suspended Au/Pd alloy coated fiber bundle at 20, 40, 60, 80, and 100 seconds.

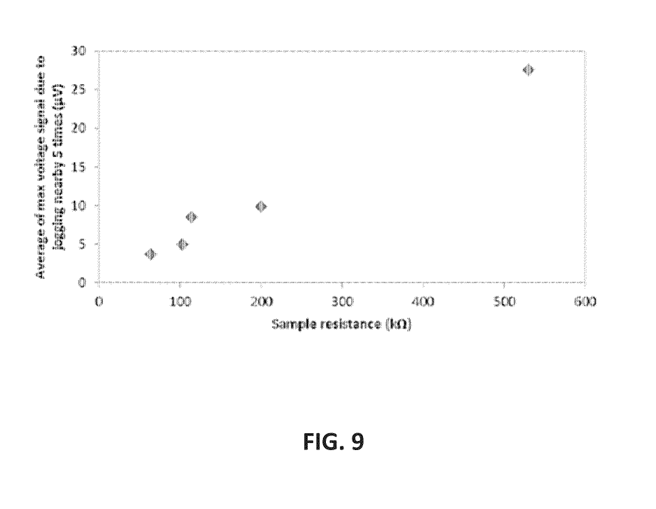

Experiments performed on Au/Pd coated fiber bundle samples of several different electrical resistances and found that the maximum voltage signal generated during nearby jogging motion increased monotonically with the sample resistance. The trend is shown in FIG. 9. Similar results were obtained for Pt coated glass fiber samples.

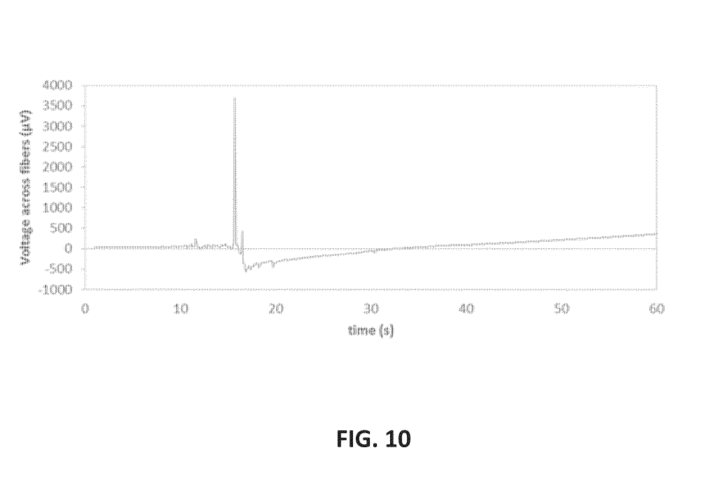

To further show the sensitivity of the fiber sensors, experiments were performed in which several fiber bundles were placed in a jar with several fruit flies. The fruit flies were encouraged to move by first hitting the jar, then the jar was placed on a stable surface and the voltage was monitored. FIG. 10 shows sample data for such an experiment. The voltage spikes between 8 and 21 seconds are due to the experimenter hitting the jar to incite the fruit flies to move. The small spike at ˜31 seconds is due to a fruit fly's motion on one of the fiber bundles, possibly causing the fibers to bend or flex. This motion was recorded in a video.

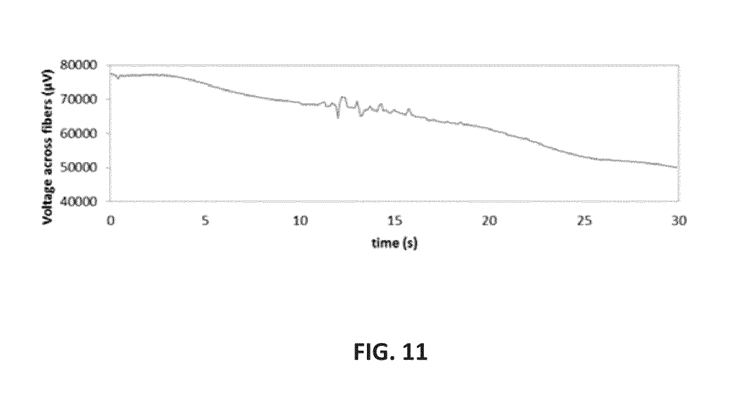

Experiments were performed on the effect of nearby motion on the voltage across coated fibers immersed in salt water. For these experiments, glass fibers were coated first with Pt (conducting layer), and then by boron nitride (for insulation from the water). A metal cylinder was rolled under water near the coated fibers and the voltage across the fibers was measured. The voltage drop was far from zero even prior to the cylinder motion; however, significant fluctuations in the voltage were observed when the water was disturbed by the cylinder's motion from 11-16 seconds. Sample results from these experiments are shown in FIG. 11.

Various aspects of different embodiments of the present invention are expressed in paragraphs X1, X2, and X3 as follows:

X1. One aspect of the present invention pertains to a sensor. The sensor preferably comprises a glass fiber coated with an electrically conducting material, the fiber having a length; a first electrical lead in electrical communication with the fiber at a first position along the length; and a second electrical lead in electrical communication with the fiber at a second position along the length, the first position being spaced apart from the second position.

X2. One aspect of the present invention pertains to a method of detecting motion of a substance. The method preferably comprises providing a substrate including a glass fiber coated with a material; exposing the substrate and glass fiber to the motion of the substance; generating a voltage by the glass fiber corresponding to the motion; and detecting the voltage.

X3. One aspect of the present invention pertains to a sensor. The sensor preferably comprises a flexible substrate coated with at least one of telluride, lead, platinum, gold, and palladium, the flexible substrate in electrical communication with a voltage measurement device.

Yet other embodiments pertain to any of the previous statements X1, X2, or X3 which are combined with one or more of the following other aspects. It is also understood that any of the aforementioned X paragraphs include listings of individual features that can be combined with individual features of other X paragraphs.

Wherein the electrically conducting material is at least one of telluride, lead, platinum, gold, and palladium.

Wherein the glass fiber is coated with lead telluride nanocrystals.

Wherein the glass fiber is coated with gold/palladium alloy.

Wherein the glass fiber is coated with platinum.

Wherein the glass fiber includes a first end and a second end opposite the first end.

Further comprising a two terminal device for detecting a voltage, wherein the first lead is connected to one terminal of the device and wherein the second lead is connected to the other terminal of the device.

Wherein the glass fiber is located underground.

Wherein the glass fiber is located underwater.

Wherein the glass fiber is a bundle of glass fibers.

Further comprising an insulating layer coated on the electrically conducting material.

Wherein the detected voltage is greater than a predetermined threshold.

Wherein the predetermined threshold is 100 μV.

Wherein the electrically conducting material includes an elemental metal or metalloid in Periods 5 or 6.

Wherein the electrically conducting material is at least one of telluride, lead, platinum, gold, and palladium.

Wherein the substance is solid, the substrate is attached to a surface of the solid substance, and said detection corresponds to motion of the solid substance.

Wherein the voltage corresponds to a change in the velocity of the surface.

Wherein the substance is liquid, the glass fiber is at least partly immersed in the liquid substance, and said detection corresponds to motion of the liquid substance.

Wherein the voltage corresponds to wave motion within the liquid substance.

Wherein the substance is gaseous, the glass is exposed to the gaseous substance, and said detection corresponds to motion of the gaseous substance.

Wherein the voltage corresponds to the flow of the gas proximate to the fiber.

Wherein said generating is by flexure of the glass fiber.

Wherein said detecting is performed with a voltage measurement device having two terminals.

Wherein said detecting is of the electrical field generated by the fiber.

Wherein the flexible substrate is a glass fiber.

Wherein the flexible substrate is coated with lead telluride.

While the inventions have been illustrated and described in detail in the drawings and foregoing description, the same is to be considered as illustrative and not restrictive in character, it being understood that only certain embodiments have been shown and described and that all changes and modifications that come within the spirit of the invention are desired to be protected.

What is claimed is:

1. A sensor, comprising:
a glass fiber coated with an electrically conducting material, the fiber having a length;
a first electrical lead in electrical communication with the fiber at a first position along the length; and
a second electrical lead in electrical communication with the fiber at a second position along the length, the first position being spaced apart from the second position.

2. The sensor of claim 1, wherein the electrically conducting material is at least one of telluride, lead, platinum, gold, and palladium.

3. The sensor of claim 2, wherein the glass fiber is coated with lead telluride nanocrystals.

4. The sensor of claim 2, wherein the glass fiber is coated with gold/palladium alloy.

5. The sensor of claim 2, wherein the glass fiber is coated with platinum.

6. The sensor of claim 1, wherein the glass fiber includes a first end and a second end opposite the first end.

7. The sensor of claim 1, further comprising a two terminal device for detecting a voltage, wherein the first lead is connected to one terminal of the device and wherein the second lead is connected to the other terminal of the device.

8. The sensor of claim 1, wherein the glass fiber is located underground.

9. The sensor of claim 1, wherein the glass fiber is located underwater.

10. The sensor of claim 1, wherein the glass fiber is a bundle of glass fibers.

11. The sensor of claim 1, wherein the coating electrically conducting material has a thickness of about 300 nm.

12. The sensor of claim 1, further comprising an insulating layer coated on the electrically conducting material.

13. A method of detecting motion of a substance, comprising:
providing a substrate including a glass fiber coated with a material;
exposing the substrate and glass fiber to the motion of the substance;
generating a voltage by the glass fiber corresponding to the motion; and
detecting the voltage.

14. The method of claim 13, wherein the detected voltage is greater than a predetermined threshold.

15. The method of claim 14, wherein the predetermined threshold is 100 μV.

16. The method of claim 13, wherein the electrically conducting material includes an elemental metal or metalloid in Periods 5 or 6.

17. The method of claim 13, wherein the electrically conducting material is at least one of telluride, lead, platinum, gold, and palladium.

18. The method of claim 13, wherein the glass fiber is a bundle of glass fibers.

19. The method of claim 13, wherein the substance is solid, the substrate is attached to a surface of the solid substance, and said detection corresponds to motion of the solid substance.

20. The method of claim 19, wherein the voltage corresponds to a change in the velocity of the surface.

21. The method of claim 13 wherein the substance is liquid, the glass fiber is at least partly immersed in the liquid substance, and said detection corresponds to motion of the liquid substance.

22. The method of claim 21 wherein the voltage corresponds to wave motion within the liquid substance.

23. The method of claim 13 wherein the substance is gaseous, the glass is exposed to the gaseous substance, and said detection corresponds to motion of the gaseous substance.

24. The method of claim 23 wherein the voltage corresponds to the flow of the gas proximate to the fiber.

25. The method of claim 13 wherein said generating is by flexure of the glass fiber.

26. The method of claim 13 wherein said detecting is performed with a voltage measurement device having two terminals.

27. The method of claim 13 wherein said detecting is of the electrical field generated by the fiber.

28. A sensor, comprising:
a flexible substrate coated with at least one of telluride, lead, platinum, gold, and palladium, the flexible substrate in electrical communication with a voltage measurement device.

29. The sensor of claim 19, wherein the flexible substrate is a glass fiber.

30. The sensor of claim 19, wherein the flexible substrate is coated with lead telluride.
